(19) United States
(12) Patent Application Publication
(10) Pub. No.: US 2011/0175635 A1
(43) Pub. Date: Jul. 21, 2011

(54) PROBE FOR ELECTRICAL TEST AND METHOD FOR MANUFACTURING THE SAME, AND ELECTRICAL CONNECTING APPARATUS AND METHOD FOR MANUFACTURING THE SAME

(75) Inventors: Daigo NAKAMURA, Aomori (JP); Takashi AKINIWA, Aomori (JP); Kenji SASAKI, Aomori (JP)

(73) Assignee: KABUSHIKI KAISHA NIHON MICRONICS, Tokyo (JP)

(21) Appl. No.: 12/984,585

(22) Filed: Jan. 4, 2011

(30) Foreign Application Priority Data
Jan. 15, 2010 (JP) 2010006946

(51) Int. Cl. G01R 1/067; G01R 31/00; H01R 43/00

(52) U.S. Cl. 324/755.01; 324/756.05; 29/825

(57) ABSTRACT

A probe for an electrical test has a foot portion coupled with a board, an arm portion extending laterally from a lower end portion of the foot portion, and a needle tip portion projecting downward from a tip end portion of the arm portion. At least one selected from a group consisting of the foot portion, the arm portion, and the needle tip portion comprises a symbol specifying a position of the probe on the board.

### PRIORITY CLAIM

The instant application claims priority to Japanese Patent Application No. 2010-006946, filed Jan. 15, 2010, which application is incorporated herein by reference in its entirety.

### TECHNICAL FIELD

An embodiment of the subject matter relates to a probe for use in an electrical test of a flat-plate-shaped device under test such as a semiconductor integrated circuit and a method for manufacturing the same and an electrical connecting apparatus and a method for manufacturing the same.

### BACKGROUND

Multiple semiconductor integrated circuits formed on a semiconductor wafer undergo an electrical test to determine whether or not they are manufactured in accordance with the specification before or after being separated into respective chips. In the electrical test of this kind, a probe assembly or an electrical connecting apparatus such as a probe card having a plurality of probes to be connected to electrodes of a device under test that is each semiconductor integrated circuit is used. The device under test is connected to an electrical circuit of a testing system via the electrical connecting apparatus.

As an example of a conventional electrical connecting apparatus of this kind, there is one having a sheet-like board made by forming a plurality of wires in a flexible insulating synthetic resin film and a plurality of probes arranged on the lower side of the board (Patent Document 1). In this electrical connecting apparatus, each probe includes a foot portion coupled with the lower side of the board, an arm portion extending laterally from the lower end portion of the foot portion, and a needle tip portion projecting downward from the tip end portion of the arm portion and is supported on the board in a cantilevered manner.

In such an electrical connecting apparatus, each probe is thrust on an electrode of a device under test at the tip end (lower end) of its needle tip portion, is elastically deformed at its arm portion, and scrapes away an oxide film on the electrode of the device under test at the tip end of its needle tip portion. Accordingly, the probes and the device under test are electrically connected.

Each probe is thrust on and released from the electrode of the device under test at the tip end of its needle tip portion in each test. As a result, each probe is damaged through such repeated thrust and release. The damage includes permanent deformation of the probe itself causing the needle tip to be displaced from a targeted position (coordinate position) with respect to the board and to be unable to contact a predetermined electrode, breakage of the probe itself or coming off of the probe itself from the board, etc.

Under the above circumstances, in the electrical connecting apparatus of this kind, repairs such as fixing of the damaged probe so that the needle tip may be located at the targeted position with respect to the board, replacement of the damaged probe with a new one, etc. are performed. For such repairs, the coordinate position of the needle tip of the probe to be repaired with respect to the board must be found.

Conventionally, since such a coordinate position of the probe to be repaired is confirmed with use of an optical microscope or the like, it takes long time to confirm the coordinate position.

### CITATION LIST

Patent Document: Japanese Patent Appln. Public Disclosure No. 2008-151573

### SUMMARY

It is an object of the embodiment of the subject matter to enable to specify a position of a probe with respect to a board easily.

A probe for an electrical test according to the present invention comprises a foot portion coupled with a board, an arm portion extending laterally from a lower end portion of the foot portion, and a needle tip portion projecting downward from a tip end portion of the arm portion, and a symbol specifying a position of the probe on the board is formed at least at one location selected from a group consisting of the foot portion, the arm portion, and the needle tip portion.

A probe for an electrical test manufactured by a method according to the embodiment of the subject matter has a foot portion coupled with a board, an arm portion extending laterally from a lower end portion of the foot portion, and a needle tip portion projecting downward from a tip end portion of the arm portion. The method for manufacturing such a probe comprises the steps of forming a foundation layer on a base table, forming, on the foundation layer, a sign that corresponds to a symbol specifying a position of the probe on the board and has a mirror-image relationship with the corresponding symbol, and forming the needle tip portion, the arm portion, and the foot portion by depositing a metal material in an area on the foundation layer including the sign.

An electrical connecting apparatus according to the embodiment of the subject matter comprises a board and a plurality of probes arranged on a lower side of the board. Each probe has a foot portion coupled with the board at a upper end portion of side foot portion, an arm portion extending laterally from a lower end portion of the foot portion, a needle tip portion projecting downward from a tip end portion of the arm portion, and a symbol specifying a position of the probe on the board, the symbol being formed at least at one location selected from a group consisting of the foot portion, the arm portion, and the needle tip portion.

Each of a plurality of probes to be used in an electrical connecting apparatus manufactured by a method according to the embodiment of the subject matter has a foot portion coupled with a board, an arm portion extending laterally from a lower end portion of the foot portion, and a needle tip portion projecting downward from a tip end portion of the arm portion. The method for manufacturing the electrical connecting apparatus having such a probe comprises the steps of forming a foundation layer on a base table, forming, on the foundation layer, a sign that corresponds to a symbol specifying a position of the probe on the board and has a mirror-image relationship with the corresponding symbol, forming the needle tip portion, the arm portion, and the foot portion by depositing a metal material in an area on the foundation layer including the sign, and forming the board having a wiring portion continuing into an upper end of the foot portion.

The arm portion may be formed in a prismatic shape, and the symbol may be formed on the arm portion.

With the embodiment of the subject matter, by determining a relationship between a position of a probe with respect to a board and a symbol described on the probe in advance, the position of the probe with respect to the board can be specified easily by the symbol described on the probe.

### BRIEF DESCRIPTION OF DRAWINGS

FIG. 1 is a plan view showing an embodiment of an electrical connecting apparatus using a probe according to the embodiment of the subject matter.

FIG. 2 is a bottom view of the electrical connecting apparatus shown in FIG. 1.

FIG. 3 is a cross-sectional view obtained along the line 3-3 in FIG. 1.

FIGS. 4 (A) and 4 (B) are enlarged cross-sectional views showing a part and its proximity of a sheet-like wiring board in the electrical connecting apparatus in FIG. 3, and FIG. 4 (A) is a partially enlarged view of the sheet-like wiring board and a block, and FIG. 4 (B) is an enlarged view of the probe and its proximity.

FIG. 5 is a perspective view showing an embodiment of the probe according to the embodiment of the subject matter.

FIGS. 6 (A)-(F) show respectively manufacturing processes of the probe and the electrical connecting apparatus according to the embodiment of the subject matter.

FIGS. 7 (A)-(E) show respectively the manufacturing process following FIG. 6 (F).

FIGS. 8 (A)-(H) show respectively the manufacturing process following FIG. 7 (E).

FIGS. 9 (A)-(G) show respectively the manufacturing process following FIG. 8 (H).

FIGS. 10 (A)-(E) show respectively the manufacturing process following FIG. 9 (G).

FIGS. 11 (A)-(C) show respectively the manufacturing process following FIG. 10 (E).

FIG. 12 shows a sign for a symbol formed in the process shown in FIG. 6 (F).

### DETAILED DESCRIPTION

Embodiments of Probe and Electrical Connecting Apparatus

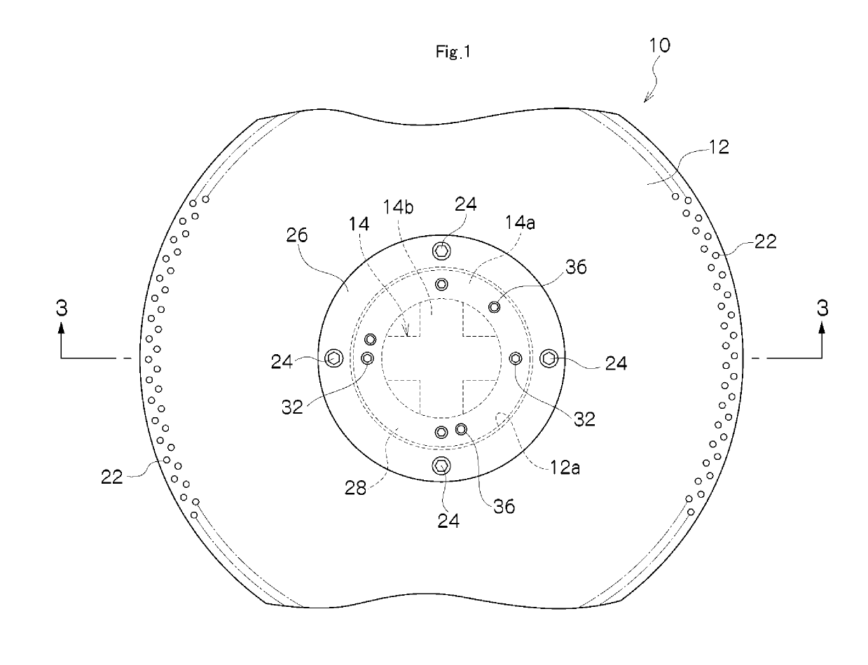

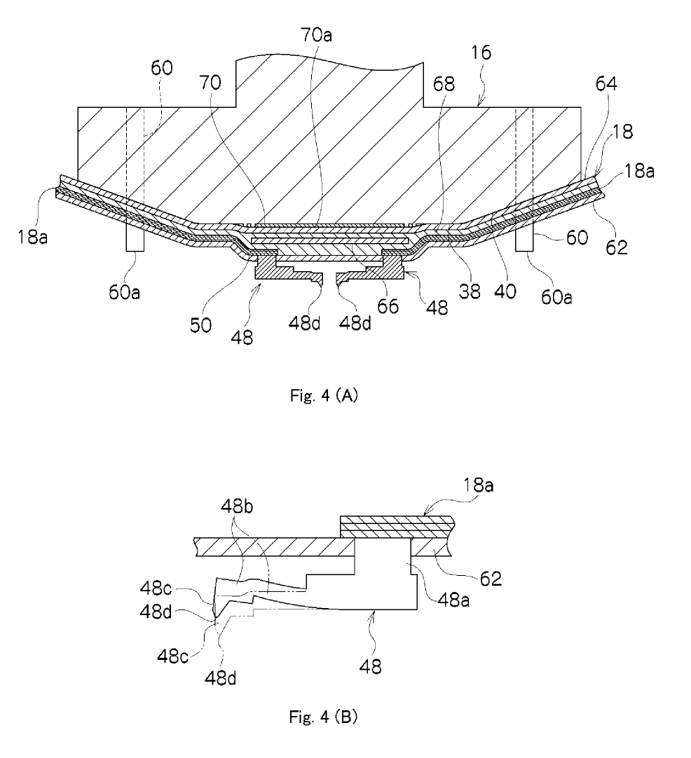

Referring to FIGS. 1 to 4, a probe assembly or an electrical connecting apparatus 10 comprises a rigid wiring board 12 arranged in parallel with a not shown testing system, a block 16 elastically supported to the rigid wiring board 12 via a spring member 14, and a flexible wiring board or a sheet-like wiring board 18 having a plurality of conductive paths 18a (refer to FIGS. 4 (A) and 4 (B)) electrically connected respectively to a plurality of not shown wiring paths of the rigid wiring board 12.

The rigid wiring board 12 has a plate-shaped electrical insulating base material made of a glass-fiber-containing epoxy resin, the aforementioned plurality of wiring paths provided in the base material, and a plurality of tester lands 22 arranged at the outer rim of the base material, as a known rigid printed wiring board. Each wiring path of the rigid wiring board 12 is connected to an electrical circuit of the not shown testing system via the corresponding tester land 22. In the example shown in the figures, a circular board having a circular opening 12a at the center is used as the rigid wiring board 12.

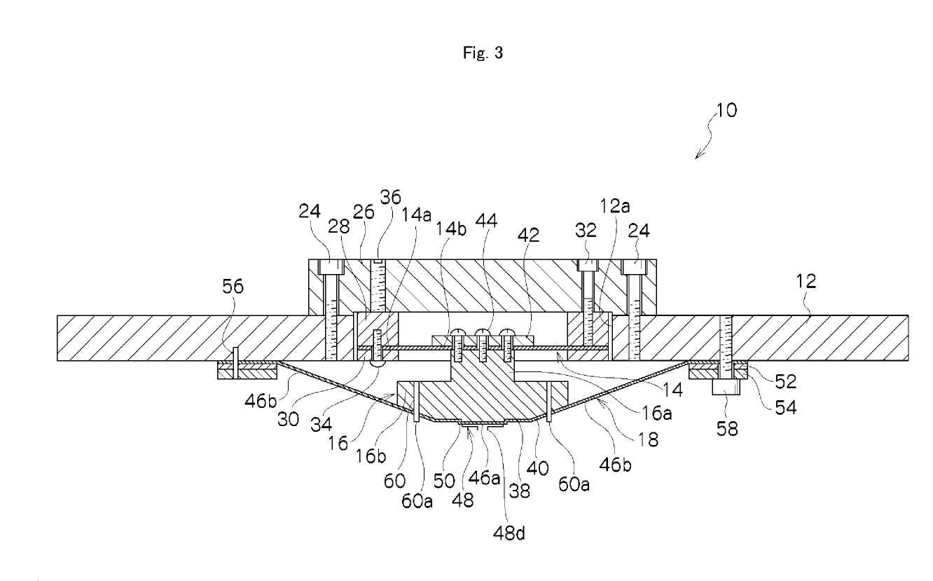

The spring member 14 is made of a plate-shaped spring material and integrally comprises an annular supporting portion 14a (refer to FIGS. 1 and 3) having a shorter outer dimension than the diameter of the circular opening 12a of the rigid wiring board 12 and a crosshair main body portion 14b (refer to FIGS. 1 and 3) arranged inside the annular supporting portion 14a as shown in FIGS. 1 and 3.

As shown in FIGS. 1 to 3, a circular supporting plate 26 made of a metal such as stainless steel is fixed on the upper surface of the rigid wiring board 12 by bolts 24 screwed in the rigid wiring board 12 at portions that do not interfere with the aforementioned wiring paths. The supporting plate 26 supports the rigid wiring board 12 and acts as a reinforcing member of the rigid wiring board 12.

As shown in FIG. 3, the spring member 14 is held in the circular opening 12a via an annular attaching plate 28 and a plurality of presser plates 30 annularly combined with one another and sandwiching the annular supporting portion 14a from both the surfaces. To hold the spring member 14 to the rigid wiring board 12, the attaching plate 28 is coupled with the lower surface of the supporting plate 26 by bolts 32, and each presser plate 30 is coupled with the attaching plate 28 by a bolt 34 penetrating the presser plate 30 and the annular supporting portion 14a of the spring member 14 and screwed in the attaching plate 28. In this manner, the spring member 14 is held to the rigid wiring board 12, lying across the circular opening 12a within the opening 12a.

Planarity adjusting screw members 36 for adjusting a holding posture of the spring member 14 in a state of loosening the bolts 32 are screwed in the supporting plate 26 so that the tip ends of planarity adjusting screw members 36 can abut on the top surface of the attaching plate 28.

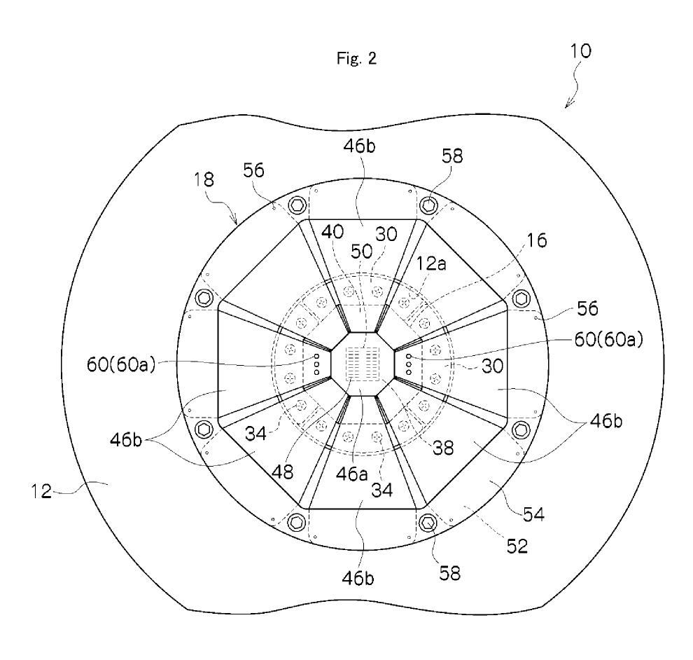

The block 16 is fixed to the main body portion 14b of the spring member 14 held in the circular opening 12a of the rigid wiring board 12. The block 16 includes a stem portion 16a having a rectangular cross-section and a supporting portion 16b having a regular octagonal cross-section and continuing into the lower end of the stem portion 16a in the example shown in the figures. An octagonal flat bottom surface 38 is formed at the center of the lower portion of the supporting portion 16b as shown in FIG. 2, and tapered surfaces 40 continuing into the respective sides of the bottom surface 38 are formed at the circumference of the bottom surface 38.

The block 16 is coupled with the main body portion 14b of the spring member 14 at the top surface of the stem portion 16a with its bottom surface 38 directed downward. For this coupling, a fixing plate 42 sandwiching the main body portion 14b in cooperation with the stem portion 16a is fixed to the stem portion 16a by screw members 44 screwed in the stem portion 16a.

As shown in FIGS. 2 and 3, the sheet-like wiring board 18 has, at its center portion, an octagonal part 46a formed to correspond to the bottom surface 38 of the block 16, and eight extending parts 46b extending outward in the radial direction from the octagonal part 46a. The center portion of the octagonal part 46a is adapted to be a contact area 50 at which multiple probes 48 are arranged with their needle tips 48d aligned. The contact area 50 is formed in a rectangular shape in the example shown in FIG. 2. As many probes 48 as the total number of electrodes in the device under test that can be tested at a time are arranged.

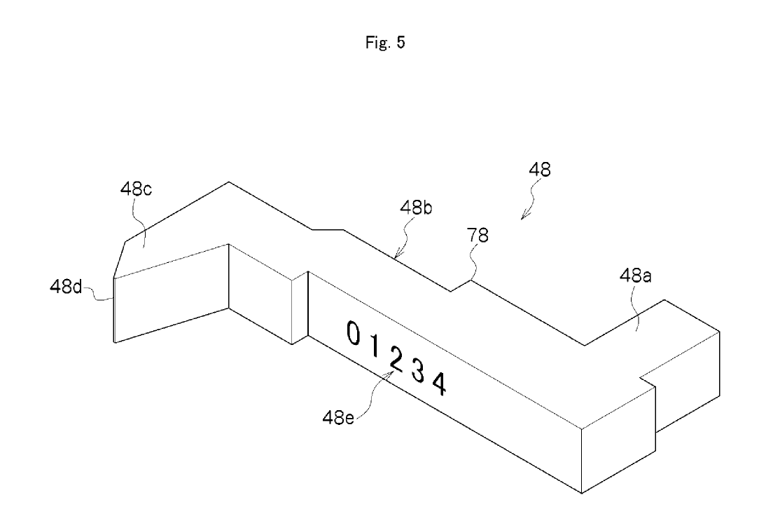

As shown in FIGS. 4 (B) and 5, each probe 48 includes a prismatic attaching portion or a foot portion 48a coupled with the lower side of the sheet-like wiring board 18, a prismatic arm portion 48b extending from the foot portion 48a in a direction intersecting with the foot portion 48a, and a needle tip portion 48c projecting to the opposite side of the foot portion 48a from the tip end portion of the arm portion 48b and is supported on the lower side of the sheet-like wiring board 18 in a cantilevered manner.

That is, each probe 48 is coupled with the lower side of the sheet-like wiring board 18 at the upper end portion of the foot portion 48a in a state where the foot portion 48a extends in the up-down direction, the arm portion 48b extends laterally from the lower end portion of the foot portion 48a, and the needle tip portion 48c projects downward from the arm portion 48b.

The arm portion 48b has a step 78 on the upper side of the rear end portion (refer to FIG. 5). The tip end portion (lower end portion) of the needle tip portion 48c is sharp-pointed, and the tip end (lower end) is adapted to be a needle tip 48d to be thrust on the electrode of the device under test. Each probe 48 has on the lower surface of the arm portion 48b a symbol 48e specifying a coordinate position of the probe 48 on the sheet-like wiring board 18.

Although the symbol 48e is a number to specify a number of the probe 48 in the example shown in the figure, another symbol such as a value representing a coordinate of the probe 48 in XY coordinates on the sheet-like wiring board 18 is also available. The symbol 48e may be provided on the upper surface or side surface of the arm portion 48b instead of on the lower surface of the arm portion 48b. Also, the symbol 48e may be provided on the foot portion 48a or the needle tip portion 48c instead of on the arm portion 48b. However, the symbol 48e is preferably provided on the lower surface of the arm portion 48b in consideration of easiness of observation (specification of the probe).

As shown in FIG. 3, the sheet-like wiring board 18 is fixed on the bottom surface 38 by adhesive with the needle tips 48d of the multiple probes 48 projecting from its contact area 50 directed downward so that the octagonal portion 46a may be supported on the bottom surface 38 at its back surface, and so that the extending parts 46b may be supported on the tapered surfaces 40. Also, the sheet-like wiring board 18 is coupled with the rigid wiring board 12 at the outer edge portions of the extending parts 46b so that the extending parts 46b may be slightly slack.

To couple the outer edge portion of the sheet-like wiring board 18 with the rigid wiring board 12, an elastic rubber ring 52 is arranged along the outer edge portion of the sheet-like wiring board 18, and a ring metal fitting 54 covering the elastic rubber ring 52 is arranged. The outer edge portion of the sheet-like wiring board 18 and both the members 52, 54 are mutually positioned against the rigid wiring board 12 by a plurality of positioning pins 56 as shown in FIG. 2.

By tightening screw members 58 penetrating the sheet-like wiring board 18 and both the members 52, 54 into the rigid wiring board 12, the sheet-like wiring board 18 is coupled with the rigid wiring board 12 at its outer edge portion. By coupling the outer edge portion with the rigid wiring board 12, the conductive paths 18a (refer to FIGS. 4 (A) and 4 (B)) of the sheet-like wiring board 18 are electrically connected to the aforementioned corresponding wiring paths of the rigid wiring board 12.

In the example shown in FIGS. 2 and 3, a plurality of alignment pins 60 are provided to penetrate the sheet-like wiring board 18. An alignment mark 60a that can be captured by a video camera supported on a supporting table supporting the device under test although not shown in figures is provided at the lower end of each alignment pin 60. Each alignment mark 60a can be a crosshair, an asterisk mark, a double circle, or a mark having different optical characteristics (especially, brightness) from those of the surroundings.

Since a relative positional information of the electrical connecting apparatus 10 to the aforementioned supporting table is obtained from a captured image of each alignment mark 60a, a relative position of the electrical connecting apparatus 10 to the aforementioned supporting table is adjusted based on this positional information so that the needle tip 48d of each probe 48 of the electrical connecting apparatus 10 may contact each corresponding electrode of the device under test on the aforementioned supporting table. Thereafter, an electrical contact is done between the needle tip 48d of each probe 48 and the corresponding electrode to perform an electrical test of the device under test by the testing system.

Referring to FIGS. 4 (A) and 4 (B), the sheet-like wiring board 18 includes a pair of mutually layered resin films 62, 64 and the conductive path 18a are formed between both the resin films 62, 64. Both the resin films 62, 64 are made of flexible electrical insulating synthetic resins such as a polyimide resin.

The conductive path 18a is in a laminated structure. This laminated structure is for example a three-layered laminated structure having a pair of first conductive material layers made of a conductive material such as copper having high conductivity suitable for being used as an electric wire and a second conductive material layer, sandwiched between the paired first conductive material layers, made of a metal material such as nickel or a nickel-phosphorus alloy having higher resiliency than the first conductive material layer. Forming the conductive path 18a in such a three-layered structure enables to heighten the strength of the conductive path 18a, prevent breakage, and improve endurance.

Each probe 48 is electrically connected to the conductive path 18a so as to penetrate one resin film 62 and project downward from the resin film 62. Also, a flat-plate-shaped reinforcing plate 66 such as ceramic having approximately the same size and shape as those of the contact area 50 (refer to FIG. 2) is buried at a position corresponding to the contact area 50 between both the resin films 62, 64 so as to cover the conductive path 18a partially.

The reinforcing plate 66 can be fixed between both the resin films 62, 64 via an adhesive sheet 68 such as a synthetic resin sheet as shown in the figures. Since such a reinforcing plate 66 has higher rigidity than the resin films 62, 64, deformation of the sheet-like wiring board 18 at a position corresponding to the reinforcing plate 66 is restricted by an external force.

A ceramic plate, which is lightweight and less thermally-deformed, is preferable as the reinforcing plate 66 although another plate-shaped member can be used. The reinforcing plate 66 made of the ceramic plate effectively restricts deformation of the sheet-like wiring board 18 caused by thermal expansion and contraction since the reinforcing plate 66 made of the ceramic plate is less likely to suffer expansion and contraction deformation by heat as well as the aforementioned deformation by an external force.

On the bottom surface 38 of the block 16 receiving the back surface of the sheet-like wiring board 18 is formed a rectangular central recess 70 opened downward. The contact area 50 of the sheet-like wiring board 18 is fixed on the bottom surface 38 of the block 16 by adhesive 70a housed in the central recess 70.

Each probe 48 is electrically connected to the conductive path 18a at the top of the foot portion 48a and is coupled with the resin film 62 at the upper portion of the foot portion 48a so that the foot portion 48a may penetrate the resin film 62 and extend downward from the conductive path 18a of the sheet-like wiring board 18, so that the arm portion 48b may extend approximately in parallel with the resin film 62 forming the lower surface of the sheet-like wiring board 18 to be spaced downward from the resin film 62, and so that the needle tip portion 48c may be away downward from the lower surface of the sheet-like wiring board 18, thus to be supported to the sheet-like wiring board 18, as shown in FIG. 4 (B).

In a state where the above electrical connecting apparatus 10 is attached to the testing system and is connected to the electrical circuit of the testing system, and where the device under test is arranged in the testing system, the needle tip 48d of each probe 48 is thrust on a predetermined electrode of the device under test. This makes the arm portion 48b of each probe 48 deformed by changing the state from one shown by the dotted line to one shown by the solid line in FIG. 4 (B), as a result of which the needle tip 48d scrapes away an oxide film of the corresponding electrode, and the probe 48 is electrically connected to the electrode.

In the above state, an electrical signal is supplied from the electrical circuit of the testing system to the device under test, and then a response signal is output from the device under test to the electrical circuit of the testing system to perform a test of the device under test. Thereafter, the thrust of the probe 48 on the device under test is released. This brings back the state of each probe 48 shown by the dotted line from the state shown by the solid line in FIG. 4 (B).

The above thrust and release of the needle tip 48d on and from the corresponding electrode are repeated in each test of the device under test. As a result, each probe 48 is damaged in such a manner as permanent deformation of the probe 48 itself causing the needle tip 48d to be displaced from a targeted coordinate position with respect to the sheet-like wiring board 18 and to be unable to contact the predetermined electrode, breakage of the probe 48 itself or coming off of the probe 48 itself from the sheet-like wiring board 18, etc.

Such a damaged probe 48 is repaired in such a manner as fixing of the damaged probe 48 so that the needle tip 48d may be located at the targeted position with respect to the sheet-like wiring board 18, replacement of the damaged probe 48 with a new one, etc. Such a repair is performed after the coordinate position of the needle tip 48d with respect to the sheet-like wiring board 18 has been specified.

Since each probe 48 has the symbol 48e that specifies the coordinate position of the probe 48 on the sheet-like wiring board 18, the coordinate position can be specified easily.

Embodiments of Methods for Manufacturing Probe and Electrical Connecting Apparatus

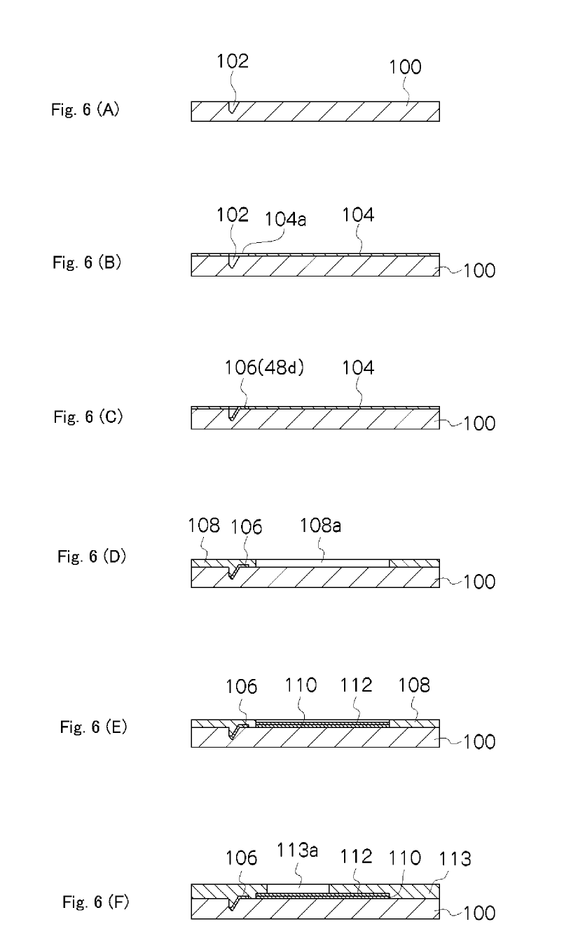

First, as shown in FIG. 6 (A), a metal plate such as a stainless steel plate is used as a base table 100, and on its surface is formed a hitting mark by an indenter to form a recess 102 for the needle tip 48d of the probe 48. Although only a single recess 102 is shown in the figure, as many recesses 102 as the number of probes 48 to be formed on the contact area 50 are actually formed with a predetermined pitch in the same arrangement state as that of the electrodes of the device under test.

Next, as shown in FIG. 6 (B), a pattern mask 104 that takes the form of the needle tip 48d of the probe 48 is formed at an area including the recess 102 by a photolithographic technique using selective exposure and development processing with photoresist. The pattern mask 104 has a plurality of patterns 104a such as openings exposing the recesses 102 and their proximity upward.

Next, as shown in FIG. 6 (C), with use of the pattern mask 104, a metal 106 for the needle tip 48d is deposited in and around the recess 102 by a deposition technique such as electroforming (electroplating), sputtering, or vapor deposition. As the metal 106, a hard metal such as rhodium or a palladium-cobalt alloy that is suitable for a material of the needle tip 48d is used.

Next, as shown in FIG. 6 (D), after removal of the pattern mask 104, a new pattern mask 108 having a plurality of patterns 108a such as openings for a sacrificial layer to be removed after completion of the sheet-like wiring board 18 is formed on the base table 100 with use of a photolithographic technique similar to one described above.

Next, as shown in FIG. 6 (E), the aforementioned sacrificial layer is formed. The sacrificial layer is formed by first depositing a nickel layer 110 in an area on the base table 100 exposed at each pattern 108a of the pattern mask 108 by a deposition technique similar to one described above and subsequently depositing a copper layer 112 on the nickel layer 110 by a deposition technique similar to one described above.

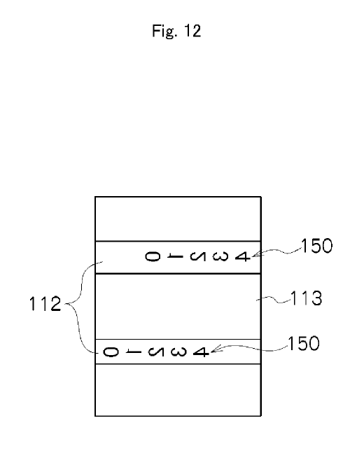

Next, as shown in FIG. 6 (F), after removal of the pattern mask 108, a new pattern mask 113 having a plurality of patterns 113a such as openings for forming a sign 150 (refer to FIG. 12) on the copper layer 112 as a foundation layer is formed on the base table 100 with use of a photolithographic technique similar to one described above.

The sign 150 is formed on the copper layer 112 to form, on the lower surface of the arm portion 48b, the symbol 48e that specifies the coordinate position of each probe 48 on the sheet-like wiring board 18, and has a mirror-image relationship with the corresponding symbol. The pattern mask 113 is used to form on the copper layer 112 as a foundation layer, the sign 150 (refer to FIG. 12) for forming on the lower surface of the arm portion 48b the symbol 48e that specifies the coordinate position of each probe 48 on the sheet-like wiring board 18.

Each sign 150 has a mirror-image relationship with the corresponding symbol 48e just like a relationship between a seal and an imprint. Such a sign 150 can be formed on the copper layer 112 as a foundation layer by an etching process. Thus, each pattern 113a of the pattern mask 113 is shaped to form a recess or a protrusion corresponding to the sign 150 on the copper layer 112.

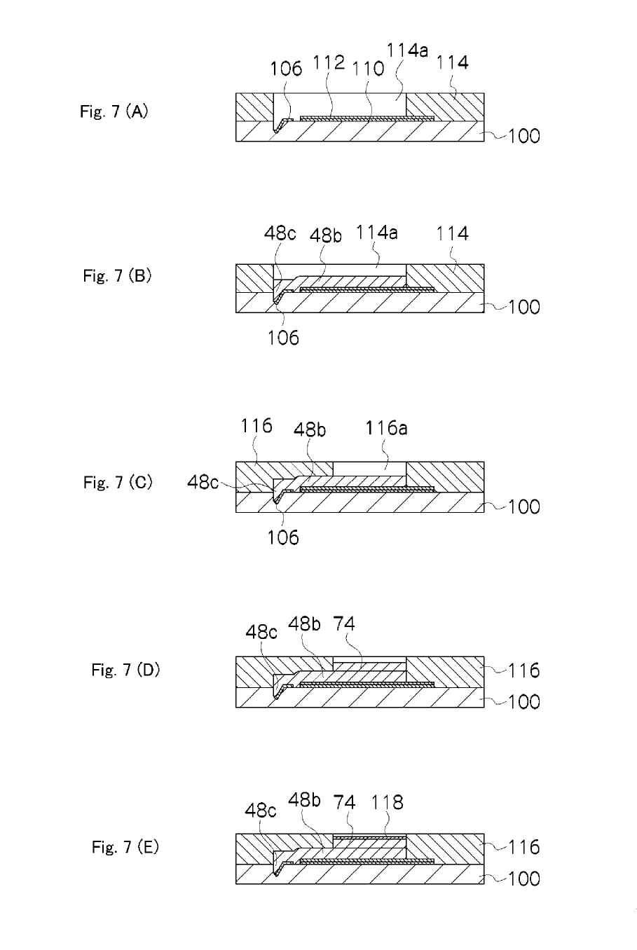

Next, as shown in FIG. 7 (A), after removal of the pattern mask 113, a new pattern mask 114 having over the metal 106 and the copper layer 112 a plurality of patterns 114a such as openings each taking the form of the arm portion 48b and the needle tip portion 48c of each probe 48 is formed with use of a photolithographic technique similar to one described above.

Next, as shown in FIG. 7 (B), a metal material such as a nickel-phosphorus alloy acting as the arm portion 48b and the needle tip portion 48c of each probe 48 is formed in an area exposed at each pattern 114a by a deposition technique similar to one described above. In this manner, the arm portion 48b and the needle tip portion 48c made of the metal material such as a nickel-phosphorus alloy are integrally formed.

It is difficult to detach the probe 48 formed by the deposition of the metal material such as a nickel-phosphorus alloy from the base table 100 made of the metal material such as stainless steel. Thus, the aforementioned copper layer 112 functions to make it easy to detach the probe 48 from the base table 100. Also, the copper layer 112 is deposited over the base table 100 via the aforementioned nickel layer 110 because it is difficult to deposit the copper layer 112 directly on the base table 100 made of stainless steel.

The arm portion 48b and the needle tip portion 48c may be formed in separate deposition processes. However, it is preferable in terms of process simplification to form the arm portion 48b and the needle tip portion 48c at the same time in a case where the arm portion 48b and the needle tip portion 48c are to be made of the same metal material.

Next, as shown in FIG. 7 (C), after removal of the pattern mask 114, a new pattern mask 116 having a plurality of patterns 116a such as openings on the upper side of the rear end portion of each arm portion 48b is formed.

Next, as shown in FIG. 7 (D), the same metal material as the arm portion 48b is deposited in each pattern 116a of the pattern mask 116 by the same technique. In this manner, a reinforcing part 74 is formed on the arm portion 48b. The reinforcing part 74 has a uniform height dimension in the longitudinal direction of the arm portion 48b. Due to this reinforcing part 74, the arm portion 48b having the step 78 (refer to FIG. 5) is formed.

Next, as shown in FIG. 7 (E), a copper layer 118 that functions as a protective layer in a perforating operation with laser described later is formed on the reinforcing part 74 by a deposition technique similar to one described above.

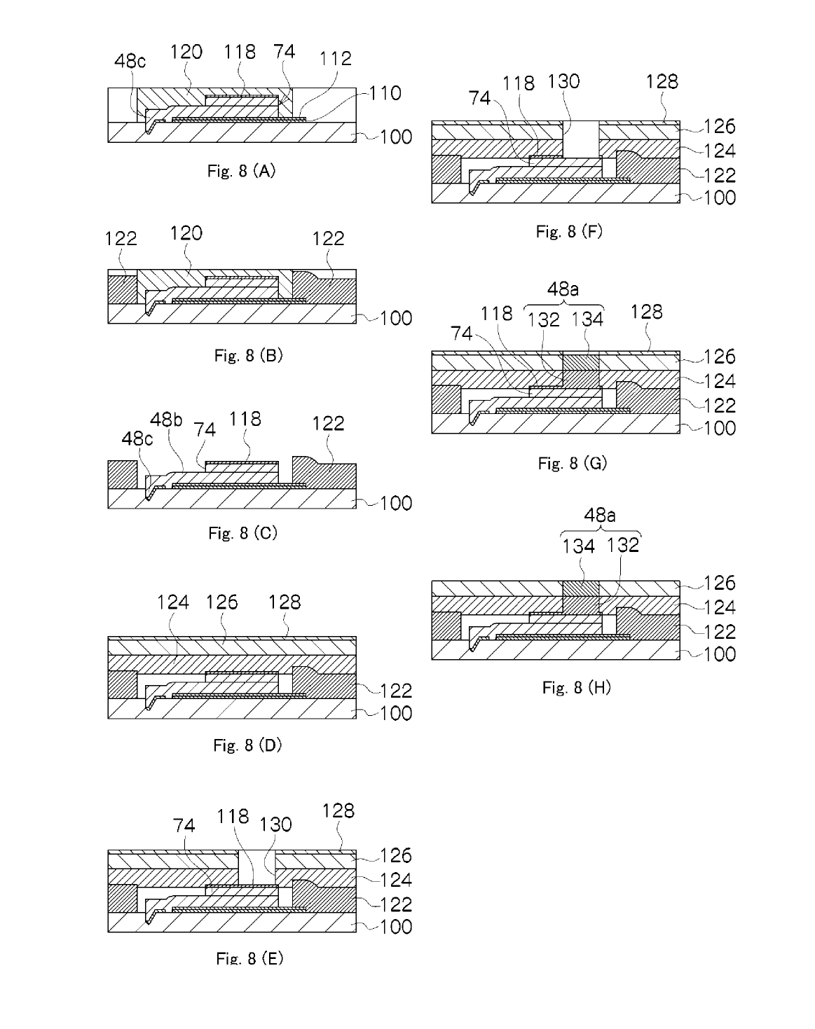

Next, as shown in FIG. 8 (A), after removal of the pattern mask 116, a pattern mask 120 for forming a second sacrificial layer that will be a reference plane of the sheet-like wiring board 18 is formed with use of a photolithographic technique similar to one described above. The pattern mask 120 is formed to cover the arm portion 48b, the needle tip portion 48c, the reinforcing part 74, and the copper layer 118.

Next, as shown in FIG. 8 (B), a metal material such as nickel for a second sacrificial layer 122 is deposited in an area on the base table 100 exposed by the pattern mask 120.

Next, as shown in FIG. 8 (C), the pattern mask 120 is removed, as a result of which the second sacrificial layer 122 as a reference plate of the sheet-like wiring board 18, the arm portion 48b, the needle tip portion 48c, the reinforcing part 74, and the copper layer 118 are exposed on the base table 100.

Next, as shown in FIG. 8 (D), a dry film 124 as a third sacrificial layer, a resin layer 126 for the first electrical insulating synthetic resin film 62 of the sheet-like wiring board 18, and a protective film 128 made of resist are sequentially formed on these exposed portions.

Next, as shown in FIG. 8 (E), in a state where the surface of the resin layer 126 or the electrical insulating synthetic resin film 62 is protected by the protective film 128, an opening 130 that reaches the copper layer 118 on the arm portion 48b is formed with use of a laser beam. The lower end of each opening 130 is an end portion of the reinforcing part 74 of the arm portion 48b located on the opposite side of the needle tip portion 48c and is opened on the copper layer 118. The copper layer 118 covers the upper surface of the reinforcing part 74 to protect the reinforcing part 74 from the laser beam.

Next, as shown in FIG. 8 (F), the copper layer 118 in the opening 130 is removed by etching, and a part of the reinforcing part 74 is exposed in the opening 130.

Next, as shown in FIG. 8 (G), a nickel layer 132 for forming the foot portion 48a of the probe 48 is deposited by a deposition technique on the reinforcing part 74 in the opening 130 so as to be integrated with the reinforcing part 74. The thickness dimension of the nickel layer 132 in the opening 130 exceeds the thickness dimension of the dry film or the third sacrificial layer 124 but never exceeds the sum of the thickness dimensions of the third sacrificial layer 124 and the resin layer 126. Thus, the upper surface of the nickel layer 132 is located within the thickness range of the resin layer 126 for the electrical insulating synthetic resin film 62.

Next, as shown in FIG. 8 (G), a copper layer 134 is deposited on the upper surface of the nickel layer 132 by a deposition technique so as to be integrated with the nickel layer 132. The dissimilar metal joint area of both the metals 132, 134 exists within the thickness range of the resin layer 126 or the electrical insulating synthetic resin film 62. The aforementioned dissimilar metal joint area is hereby protected by the electrical insulating synthetic resin film 126 (62). The copper layer 134 has a thickness dimension enough for the upper surface of the copper layer 134 to approximately correspond to the upper surface of the resin layer 126.

The protective film 128 is removed after deposition of the copper layer 134 as shown in FIG. 8 (H).

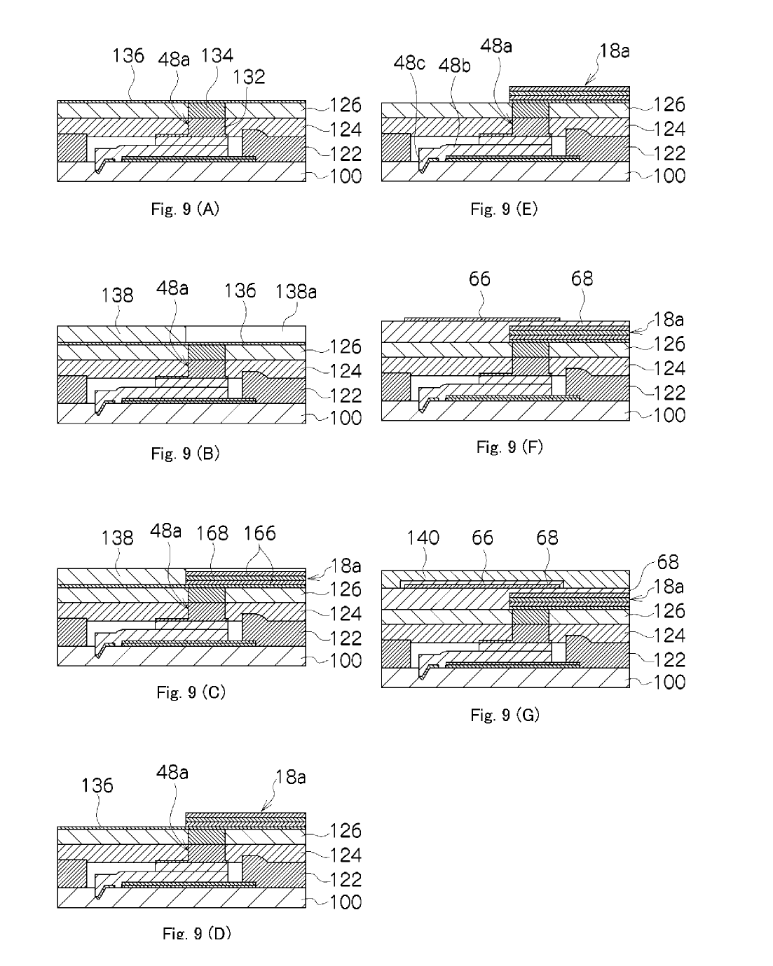

Next, as shown in FIG. 9 (A), a copper layer 136 having a thickness dimension of, for example, 0.3 μm for growing the conductive path 18a is formed by sputtering on the resin layer 126 and the copper layer 134 exposed as a result of removal of the protective film 128.

Next, as shown in FIG. 9 (B), a pattern mask 138 having a plurality of patterns 138a such as openings each taking the form of the conductive path area on the copper layer 136 is formed by a photolithographic technique.

Next, as shown in FIG. 9 (C), in an area exposed at each pattern 138a of the pattern mask 138 are sequentially formed a copper layer 166 having a thickness dimension of 10 μm, a nickel layer 168 having a thickness dimension of 2 μm, and a copper layer 166 having a thickness dimension of 10 μm for the conductive path 18a by a deposition technique similar to one described above.

Next, as shown in FIG. 9 (D), after the conductive path 18a is formed as a result of deposition of the copper layer 166, the nickel layer 168, and the copper layer 166, the pattern mask 138 is removed.

Next, as shown in FIG. 9 (E), a part of the copper layer 136 running off from the conductive path 18a is removed by etching. In this manner, the conductive path 18a excellent in strength against breakage is formed.

Next, as shown in FIG. 9 (F), on the resin layer 126 or the electrical insulating synthetic resin film 62, exposed as a result of removal of the pattern mask 138 and partial removal of the copper layer 136, and the conductive path 18a on the film, an adhesive sheet 68 made of a synthetic resin material is bonded, and the reinforcing plate 66 covering the contact area 50 is arranged on the sheet 68.

Next, as shown in FIG. 9 (G), a similar adhesive sheet 68 is arranged to cover the reinforcing plate 66.

Next, as shown in FIG. 9 (G), a polyimide resin layer 140 for forming the other electrical insulating synthetic resin film 64 is formed to cover the adhesive sheet 68, the reinforcing plate 66, and the adhesive sheet 68 by a deposition technique.

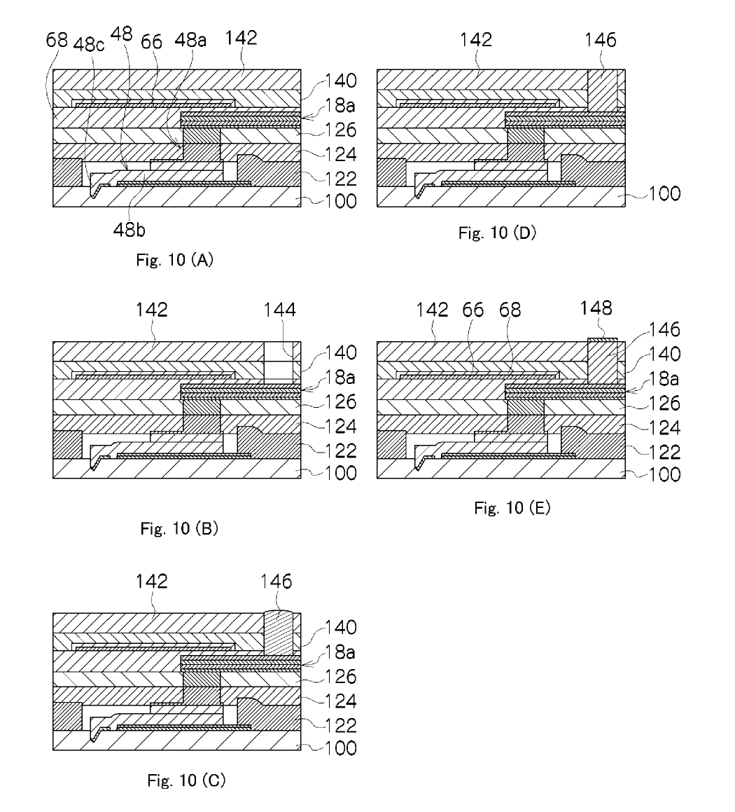

Next, as shown in FIG. 10 (A), a dry film 142 is bonded on the polyimide resin layer 140 as a fourth sacrificial layer.

Next, as shown in FIG. 10 (B), an opening 144 opened on a part of the conductive path 18a via the adhesive sheet 68, the overlying polyimide resin layer 140, and the overlying fourth sacrificial layer 142 is formed by a laser beam.

A metal material for a pad or a bump 146 is formed in this opening 144 by a deposition technique similar to one described above, as shown in FIG. 10 (C). As a metal material for the bump 146, nickel may be used.

Next, as shown in FIG. 10 (D), a part of the bump 146 protruded from the surface of the fourth sacrificial layer 142 undergoes an abrasion process so as to be flat. A gold layer 148 for favorable electrical contact with the aforementioned wiring path of the rigid wiring board 12 is formed On the flat surface of the bump 146 by a deposition technique similar to one described above, as shown in FIG. 10 (E).

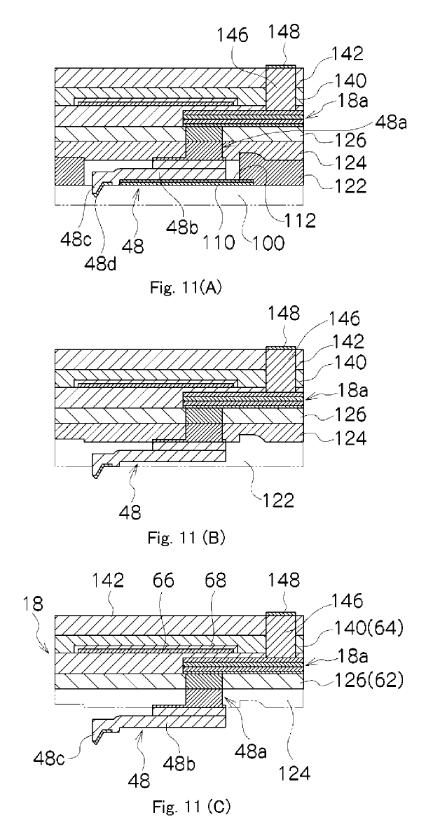

Next, as shown in FIG. 11 (A), the sheet-like wiring board 18 is removed (detached) from the base table 100 together with the second sacrificial layer 122, the fourth sacrificial layer 142, and so on. At this moment, even if part of the detaching force acts as a bending force on the contact area 50 of the sheet-like wiring board 18 via the probes 48, deformation of the contact area 50 is restricted by the reinforcing plate 66 buried inside the contact area 50. Accordingly, displacement of the needle tip 48d and the posture of each probe 48 caused by this detaching force is prevented.

Next, as shown in FIG. 11 (B), the aforementioned first sacrificial layer consisting of the nickel layer 110 and the copper layer 112 and the second sacrificial layer 122 are removed by an etching process. Also, as shown in FIG. 11 (C), the dry film 124 exposed as a result of removal of the second sacrificial layer 122 is removed, and the fourth sacrificial layer 142 is removed.

Thereafter, the outline of the sheet-like wiring board 18 shown in FIG. 2 is set by a laser process or a cutting process by means of a cutter, and openings that receive the positioning pins 56 and elongated holes that receive the alignment pins 60 are respectively formed at locations that are not in the way of the conductive paths 18a of the sheet-like wiring board 18, thus to form the sheet-like wiring board 18.

With the above manufacturing methods, since the probes 48 and the sheet-like wiring board 18 are manufactured integrally in a sequential process, the assembly in which the probes 48 and the sheet-like wiring board 18 are coupled with one another firmly can be obtained easily. Also, in the middle of such a manufacturing process, the symbol 48e that specifies the position of each probe 48 with respect to the sheet-like wiring board 18 can be formed on the probe 48 easily.

### INDUSTRIAL APPLICABILITY

The described subject matter is not limited to the above embodiments but may be altered in various ways without departing from the spirit and scope of the embodiment of the subject matter.

### REFERENCE SIGNS LIST

10: Electrical connecting apparatus
12: Rigid wiring board
16: Block
18: sheet-like wiring board
18a: Conductive path
48: Probe
48a: Foot portion
48b: Arm portion
48c: Needle tip portion
48d: Needle tip
48e: Symbol
150: Sign corresponding to a symbol

What is claimed is:

1. A probe for an electrical test comprising:
a foot portion coupled with a board;
an arm portion extending laterally from a lower end portion of said foot portion; and
a needle tip portion projecting downward from a tip end portion of said arm portion;
wherein a symbol specifying a position of said probe on said board is formed at least at one location selected from a group consisting of said foot portion, said arm portion, and said needle tip portion.

2. The probe according to claim 1, wherein said arm portion is formed in a prismatic shape, and said symbol is formed at said arm portion.

3. A method for manufacturing a probe for an electrical test having a foot portion coupled with a board, an arm portion extending laterally from a lower end portion of said foot portion, and a needle tip portion projecting downward from a tip end portion of said arm portion, comprising the steps of:
forming a foundation layer on a base table;
forming, on said foundation layer, a sign that corresponds to a symbol specifying a position of said probe on said board and has a mirror-image relationship with said corresponding symbol; and
forming said needle tip portion, said arm portion, and said foot portion by depositing a metal material in an area on said foundation layer including said sign.

4. An electrical connecting apparatus comprising:
a board; and
a plurality of probes arranged on a lower side of said board;
wherein each probe has a foot portion coupled with said board at a upper end portion of said foot portion, an arm portion extending laterally from a lower end portion of said foot portion, a needle tip portion projecting downward from a tip end portion of said arm portion, and a symbol specifying a position of said probe on said board, the symbol being formed at least at one location selected from a group consisting of said foot portion, said arm portion, and said needle tip portion.

5. The electrical connecting apparatus according to claim 4, wherein said arm portion is formed in a prismatic shape, and said symbol is formed on a lower surface of said arm portion.

6. A method for manufacturing an electrical connecting apparatus having a plurality of probes each having a foot portion coupled with a board, an arm portion extending laterally from a lower end portion of said foot portion, and a needle tip portion projecting downward from a tip end portion of said arm portion, comprising the steps of:
forming a foundation layer on a base table;
forming, on said foundation layer, a sign that corresponds to a symbol specifying a position of said probe on said board and has a mirror-image relationship with said corresponding symbol;
forming said needle tip portion, said arm portion, and said foot portion by depositing a metal material in an area on said foundation layer including said sign; and
forming said board having a wiring portion continuing into an upper end of said foot portion.
